(19) United States
(12) Patent Application Publication
(10) Pub. No.: US 2022/0295650 A1
(43) Pub. Date: Sep. 15, 2022

(54) ELECTRONIC APPARATUS

(71) Applicant: Lenovo (Beijing) Limited, Beijing (CN)

(72) Inventors: Ke SHANG, Beijing (CN); Feijun WENG, Beijing (CN)

(21) Appl. No.: 17/550,346

(22) Filed: Dec. 14, 2021

(30) Foreign Application Priority Data
Mar. 12, 2021 (CN) 202110272508.7

(51) Int. Cl. H05K 5/02; G06F 1/16; H05K 5/00

(52) U.S. Cl. CPC H05K 5/0217; G06F 1/1618; H05K 5/0017

(57) ABSTRACT

An electronic apparatus includes a first body, a second body, a flexible screen assembly, and a driver. The first body includes a first surface. The second body is rotatably connected to the first body and includes a second surface neighboring to the first surface. The first surface and the second surface form a folded state with an included angle not greater than a predetermined angle and an unfolded state with the included angle greater than the predetermined angle. The flexible screen assembly includes a first member and a second member. In the folded state, the first member is connected to the first body and covers the first surface. The second member is slidably connected to the second body. The driver is connected to the flexible screen assembly and configured to drive the flexible screen assembly to move in a first direction in the unfolded state.

### CROSS-REFERENCE TO RELATED APPLICATION

This application claims priority to Chinese Patent Application No. 202110272508.7, filed on Mar. 12, 2021, the entire content of which is incorporated herein by reference.

### TECHNICAL FIELD

The present disclosure generally relates to the electronic apparatus technology field and, more particularly, to an electronic apparatus.

### BACKGROUND

For electronic apparatuses such as a notebook computer and a cellphone, displays are fixed on one or both surfaces. The displays cannot be moved. Thus, an application method of the electronic apparatuses is limited, which makes it difficult to satisfy the increasing user requirements.

### SUMMARY

Embodiments of the present disclosure provide an electronic apparatus, including a first body, a second body, a flexible screen assembly, and a driver. The first body includes a first surface. The second body is rotatably connected to the first body and includes a second surface neighboring to the first surface. The first surface and the second surface form a folded state with an included angle not greater than a predetermined angle and an unfolded state with the included angle greater than the predetermined angle. The flexible screen assembly includes a first member and a second member. In the folded state, the first member is connected to the first body and covering the first surface. The second member is slidably connected to the second body. The driver is connected to the flexible screen assembly and configured to drive the flexible screen assembly to move in a first direction in the unfolded state. The first direction is a direction from the second body to the first body.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of an electronic apparatus in a folded state according to some embodiments of the present disclosure.

FIG. 2 illustrates a schematic structural diagram of the electronic apparatus in an unfolded state according to some embodiments of the present disclosure.

FIG. 3 illustrates a schematic structural diagram of another electronic apparatus in a folded state according to some other embodiments of the present disclosure.

FIG. 4 illustrates a schematic structural diagram of another electronic apparatus in an unfolded state according to some other embodiments of the present disclosure.

Reference numerals: 100-Electronic apparatus, 110-First body, 111-First surface, 112-Fixed member, 113-Slide member, 120-Second body, 121-Second surface, 122-Functional area, 123-Accommodation chamber, 130-Flexible screen assembly, 131-First member, 132- Second member, 140-driver, 141-First driver, 142-Second driver.

### DETAILED DESCRIPTION OF THE EMBODIMENTS

Specific technical features in various embodiments described in specific implementations may be combined in various ways without contradiction. For example, different specific technical features may be combined to form different implementations. In order to avoid unnecessary repetition, possible combinations having the specific technical features will not be described separately in the present disclosure.

In the description of embodiments of the present disclosure, unless otherwise specified and limited, the term “connected” should be understood in a broad sense. For example, “connected” may be directly connected or indirectly connected through an intermediate medium. For those of ordinary skill in the art, the specific meaning of the above term may be understood according to a specific situation.

The terms “first\second” in embodiments of the present disclosure only distinguish similar objects and do not represent a specific order for the objects. The specific order or precedence of the term “first\second” can be interchanged in allowed conditions. The objects distinguished by “first\second” can be interchanged under appropriate conditions so that embodiments of the present disclosure described herein may be implemented in a sequence other than those illustrated or described herein.

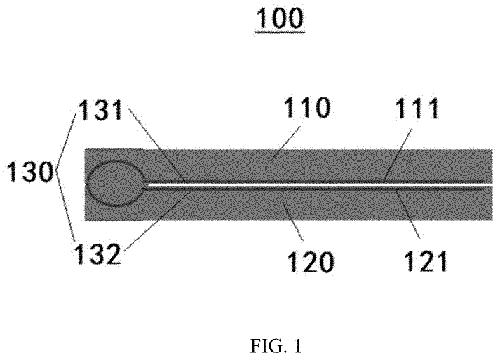

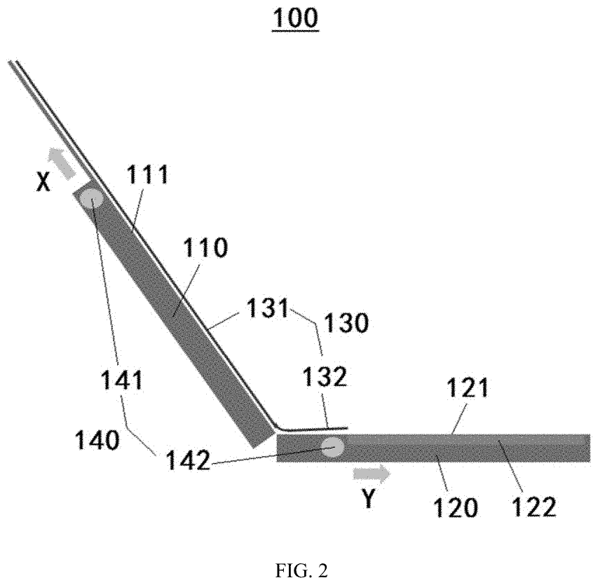

As shown in FIG. 1 and FIG. 2, embodiments of the present disclosure provide an electronic apparatus 100. The electronic apparatus includes a first body 110, a second body 120, a flexible screen assembly 130, and a driver 140.

As shown in FIG. 2, the first body 110 includes a first surface 111. In some embodiments, the first body 110 may be in a plate shape. That is, a length of the first body 110 in a length direction and a width in a width direction may be both much greater than a height in a height direction. In the case of the first body 110 being of the plate shape, the first surface 111 is an upper surface of the first body 110. The first surface 111 may be a rectangular shape, a circular shape, an oval shape, etc.

As shown in FIG. 2, the second body 120 includes a second surface 121. The second surface 121 is neighboring to the first surface 111. In some embodiments, the second body 120 may be in a plate shape. That is, a length of the second body 120 in the length direction and a width in the width direction may be both much greater than a height in the height direction. When the second body 120 is of the plate shape, the second surface 121 is a lower surface of the second body 120. The second surface 121 may be a rectangular shape, a circular shape, an oval shape, etc. The second body 120 is rotatably connected to the first body 110. In some embodiments, the second body 120 may be hinged to the first body 110 through a hinge. A rotation axis of the second body 120 relative to the first body 110 may be arranged at a position close to the first surface 111. In this case, during the rotation of the second body 120 relative to the first body 110, the second body 120 and the first body 110 may remain tightly connected at the position of the rotation axis. Thus, an edge of the first surface 111 and an edge of the second body 110 may be always connected. During the rotation, the first surface 111 and the second surface 121 may cross a predetermined angle. That is, an included angle between the first surface 111 and the second surface 121 may be greater than the predetermined angle or may not be greater than the predetermined angle. When the included angle between the first surface 111 and the second surface 121 is greater than the predetermined angle, the electronic apparatus 100 may be in an unfolded state. When the included angle between the first surface 111 and the second surface 121 is not greater than the predetermined angle, the electronic apparatus 100 may be in a folded state. In some embodiments, the predetermined angle may range from 30° to 120° , for example, 90° . That is, when the included angle between the first surface 111 and the second surface 121 is greater than 90° , the electronic apparatus 100 may be considered to be in the unfolded state. When the included angle between the first surface 111 and the second surface 121 is less than or equal to 90° , the electronic apparatus 100 may be considered to be in the folded state.

As shown in FIG. 2, the flexible screen assembly 130 includes a first member 131 and a second member 132. The first member 131 is connected to the first body 110. The second member 132 is connected to the second body 120. The first member 131 and the second member 132 may be an integral structure. The first member 131 is a member of the flexible screen assembly 130 that covers the first surface 111 in the folded state. The second member 132 is a member other than the first member 131 of the flexible screen assembly 130. In some embodiments, the second member 132 may be located in the second body 120, cover the second surface 121, or be located under the lower surface of the second body 120. The second member 132 may be slidably connected to the second body 120 to facilitate the second member 132 to slide relative to the second body 120. When a part or all of the second member 132 moves to cover the first surface 111, the part or all of the second member 132 that originally covers the first surface 111 may be transformed into the first member 131.

In embodiments of the present disclosure, the back of the first member of the flexible screen assembly may be supported by a plate-shaped structure with high structural strength. In some embodiments, the plate-shaped structure may be a steel plate. Since the first member of the flexible screen assembly does not need to be bent during the operation process, using the plate- shaped structure to support the first member will not affect the normal operation of the flexible screen assembly. Moreover, since the flexible screen assembly moves in a first direction in the unfolded state, the first body may be difficult to support all of the first member of the flexible screen assembly. Using the steel plate may ensure that the flexible screen assembly may be firmly supported in the unfolded state to ensure that the working surface of the flexible screen assembly may be maintained in a horizontal plane in the unfolded state.

As shown in FIG. 2, the driver 140 is connected to the flexible screen assembly 130 and configured to drive the flexible screen assembly 130 to move in the first direction in the unfolded state. In some embodiments, an output member of the driver 140 may be connected to the flexible screen assembly 130 to drive the flexible screen assembly 130 to move along the first direction during the rotation or retractable motion of the output member of the driver 140. The first direction is a direction from the second body 120 to the first body 110 (X direction in FIG. 2). Therefore, the flexible screen assembly 130 may move in the direction from the second member 132 to the first member 131. In the movement process, at least a part of the second member 132 may be gradually transformed into the first member 131. Thus, the area of the first member 131 may gradually increase to satisfy a display area requirement.

The electronic apparatus 100 of embodiments of the present disclosure includes the first body 110, the second body 120, the flexible screen assembly 130, and the driver 140. The first body 110 includes the first surface 111. The second body 120 is rotatably connected to the first body 110 and includes a second surface 121 neighboring to the first surface 111. The first surface 111 and the second surface 121 may be in the folded state with the included angle not greater than the predetermined angle and in the unfolded state with the included angle greater than the predetermined angle. The flexible screen assembly 130 includes the first member 131 and the second member 132. In the folded state, the first member 131 is connected to the first body 110 and covers the first surface 111. The second member 132 is slidably connected to the second body 120. In the unfolded state, the flexible screen assembly 130 may be used while maintaining an initial state or be driven by the driver 140 to move in the direction from the second body 120 to the first body 110. That is, the first member 131 may move in a direction and face away from the second member 132 to adjust the position of the flexible screen assembly 130. The flexible screen assembly 130 may be used in an adjusted state. Thus, the flexible screen assembly 130 of the electronic apparatus 100 may move relative to the first body 110 and the second body 120 to realize a plurality of application manners and satisfy the increasing application requirements.

In embodiments of the present disclosure, in the folded state, the second member may cover the second surface or be located in the second body, which is described separately below.

As shown in FIG. 1 and FIG. 2, the second member 132 covers the second surface 121. That is, the second member 132 is arranged on the upper surface of the second body 120 (as shown in FIG. 1). In the unfolded state (as shown in FIG. 2), both the first member 131 and the second member 132 are exposed. A surface of the first member 131 facing away from the body and a surface of the second member 132 facing away from the body may be used as a portion of a display surface. Thus, the first member 131 and the second member 132 may jointly form the display surface. When the included angle between the first surface 111 and the second surface 121 is a flat angle, the display surface may be a flat surface, which not only effectively satisfies the display area requirement, but also avoids an impact on viewing experience due to bending of the display surface. In addition, in the unfolded state, as the flexible screen assembly 130 moves in the first direction, the second member 132 cannot cover the second surface 121. At least a portion of the second surface 121 may be exposed. A part or all of the second surface 121 may be set as a functional area 122. When the second surface 121 is at least partially exposed, the functional area 122 may be partially or fully exposed. The functional area 122 may include at least one of a keyboard or a touchpad. The exposed functional area 122 may facilitate a user to operate, thereby satisfying a requirement for convenient operation.

As shown in FIG. 2, in embodiments of the present disclosure, the driver 140 includes a first driver 141 and a second driver 142. The first driver 141 is arranged on the first body 110 and configured to drive the flexible screen assembly 130 to move in the first direction. In some embodiments, the first driver 141 may be fixedly connected to the first body 110. For example, the first driver 141 may be fixedly connected to the first body 110 by screws or welding. The output member of the first driver 141 can be transmission-connected to the flexible screen assembly 130. When the output member of the first driver 141 is transmission-connected to the flexible screen assembly 130, the output member may drive the flexible screen assembly 130 to move. When the first driver 141 is in a working state, the output member may drive the flexible screen assembly 130 to move in the first direction by rotation or retractable motion. The second driver 142 is arranged on the second body 120 and configured to drive the flexible screen assembly 130 to move in a direction opposite to the first direction.

In some embodiments, the second driver 142 may be fixedly connected to the second body 120. For example, the second driver 142 may be fixedly connected to the second body 120 by screws or welding. The output member of the second driver 142 may be transmission- connected to the flexible screen assembly 130. When the second driver 142 is in the working state, the output member may drive the flexible screen assembly 130 in the direction opposite to the first direction by rotation or retractable motion. When the electronic apparatus 100 is in the unfolded state and needs to be in the application state where the functional area 122 is exposed, only the first driver 141 may need to be controlled to drive the flexible screen assembly 130 to move in the first direction to expose the functional area 122. When the electronic apparatus 100 is in the unfolded state and needs to be in a storage state where the functional area 122 is hidden, only the second driver 142 may need to be controlled to drive the flexible screen assembly 130 to move in the direction opposite to the first direction to hide the functional area 122. In a state where the functional area 122 is hidden, the electronic apparatus 100 may freely switch between the unfolded state and the folded state.

In some other embodiments of the present disclosure, the first driver and the second driver may also work synchronously. That is, the first driver and the second driver can not only synchronously drive the flexible screen assembly to move in the first direction, but also can synchronously drive the flexible screen assembly to move in the direction opposite to the first direction. In this situation, since the first driver and the second driver drive the flexible screen assembly synchronously, a driving process may be smooth. Moreover, if any one of the first driver and the second driver fails, the other one may still complete the work of driving the flexible screen assembly to move in the first direction or in the direction opposite to the first direction. Thus, the normal operation of the electronic apparatus may be effectively guaranteed.

As shown in FIG. 2, in embodiments of the present disclosure, the first driver 141 is close to an end of the second surface 121 away from the first surface 111. When the first driver 141 drives the flexible screen assembly 130 to move in the first direction, the first driver 141 may drive the first member 131 to move in the first direction. The first member 131 may drive the second member 132 to move in the first direction. During an entire process of the flexible screen assembly 130 moving in the first direction, most part of the flexible screen 130 may be subjected to a tensile force so that the flexible screen component 130 may remain flat, which effectively prevents the flexible screen component 130 from being squeezed to generate wrinkles.

As shown in FIG. 2, in embodiments of the present disclosure, the second driver 142 is close to an end of the functional area 122 close to the second surface 121. When the second driver 142 drives the flexible screen assembly 130 to move along the direction opposite to the first direction, the second driver 142 may drive the second member 132 to move in the direction opposite to the first direction. The second member 132 may drive the first member 131 to move in the direction opposite to the first direction. During the entire process of the flexible screen assembly 130 moving in the direction opposite to the first direction, most part of the flexible screen assembly 130 may be subjected to a tensile force so that the flexible screen assembly 130 may remain complete, which effectively prevents the flexible screen assembly 130 from being squeezed to generate wrinkles.

As shown in FIG. 2, in embodiments of the present disclosure, the first member 131 is slidably connected to the first body 110. A sliding direction of the first member 131 relative to the first body 110 may be the first direction or the direction opposite to the first direction. In some embodiments, the first surface 111 may include a guide groove, and the second surface 121 may also include a guide groove. The guide groove of the first surface 111 and the guide groove of the second surface 121 may cooperate with each other. In some embodiments, the cooperation with each other may refer to that the flexible screen assembly 130 may be partially located in the guide groove of the first surface 111 and, meanwhile, may be partially located in the guide groove of the second surface 121. The flexible screen assembly 130 may freely slide in the first guide groove and the second guide groove to move in the first direction or the direction opposite to the first direction. Thus, the flexible screen assembly 130 can not only be slidably connected to the first body 110, but also can be slidably connected to the second body 120. The flexible screen assembly 130 may slide from a position with half part of the flexible screen assembly 130 close to the first body 110 to a position with most or the entire part of the flexible screen assembly 130 close to the first body 110.

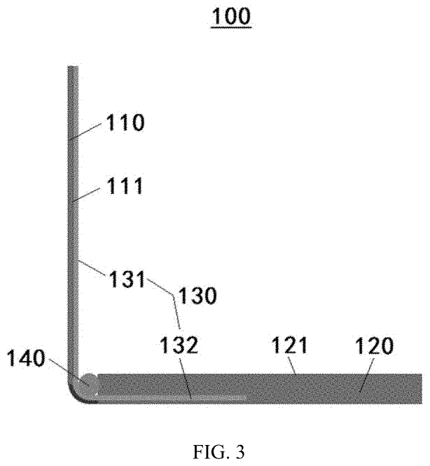

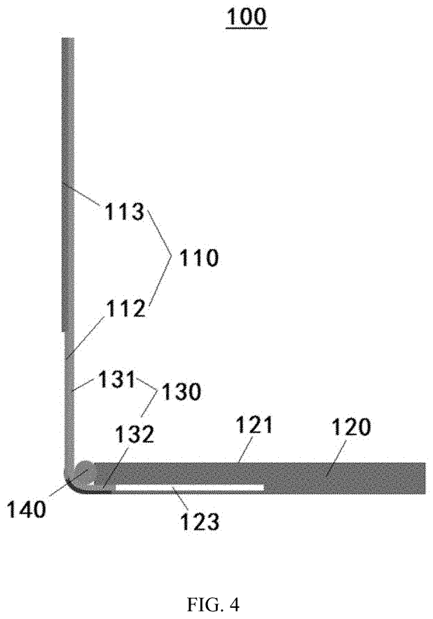

As shown in FIG. 3 and FIG. 4, when the second member 132 is located in the second body 120, the second body 120 may include an accommodation chamber 123 (as shown in FIG. 4). In some embodiments, an opening of the accommodation chamber 123 may be arranged on a side of the second body 120 close to the first body 110 so that the flexible screen assembly 130 can be extended into the accommodation chamber 123. In the folded state, the first member 131 may cover the first surface 111, and the second member 132 may be located in the accommodation chamber 123. Since the second member 132 does not cover the second surface 121, the second surface 121 will always be exposed in the unfolded state. The functional area 122 may be arranged on the second surface 121, which facilitates the user to operate in the unfolded state. The functional area 122 may include at least one of a keyboard and a touchpad. The exposed functional area 122 may facilitate the user to operate, thereby satisfying the need for convenient operation. Moreover, in the unfolded state, as the first body 110 moves in the first direction, the second member 132 originally located in the accommodation chamber 123 may gradually transform into a portion of the first member 131. The display surface of the first member 131 is a horizontal plane, which can ensure the user viewing experience.

As shown in FIG. 4, in some other embodiments of the present disclosure, the first body 110 includes a fixed member 112 and a slide member 113. The fixed member 112 is rotatably connected to the second body 120. Thus, the first surface 111 and the second surface 121 may be at different angles such that the electronic apparatus 100 may be switched between the folded state and the unfolded state. The slide member 113 is slidably connected to the fixed member 112. The sliding direction of the slide member 113 relative to the fixed member 112 is in the direction of approaching and away from the rotation axis of the fixed member 112. That is, the slide member 113 may slide relative to the fixed member 112 and approach to or be away from the rotation axis of the fixed member 112. The first surface 111 is located at the slide member 113. The sliding direction of the slide member 113 relative to the fixed member 112 may be parallel to the first surface 111. Thus, when the slide member 113 slides relative to the fixed member 112, the included angle between the first surface 111 and the second surface 121 may remain unchanged. The first member 131 may be fixedly connected to the slide member 113. When the flexible screen assembly 130 moves in the first direction, the slide member 113 may drive the flexible screen assembly 130 to move together in the first direction. The first member 131 may drive the second member 132 located in the accommodation chamber 123 to move out of the accommodation chamber 123. The portion moved out may transform into the first member 131, such that the area of the first member 131 may be increased to satisfy the display area requirement.

When the flexible screen assembly is in the storage state, the slide member may be filled between the flexible screen assembly and the fixed member. When the flexible screen assembly is in the unfolded state, the fixed member may move in the first direction. When the fixed member moves in the first direction, a cavity may appear in a part of the area between the flexible screen assembly and the fixed member because no slide member exists. The first member of the flexible screen assembly is supported by the plate-shaped structure with high structural strength. Thus, even if the cavity of the part of the area between the flexible screen assembly and the fixed member appears, the working surface of the flexible screen assembly may still remain horizontal in the unfolded state.

In embodiments of the present disclosure, the flexible screen assembly may include a flexible screen and a transmission member. The flexible screen may be configured to cover the first surface. The flexible screen may include a display area for the user to watch. The display area may face away from the first surface. When the electronic apparatus is in the unfolded state, the display area may be exposed. The transmission member may be connected to the driver, such that the driver may drive the flexible screen to move in the first direction. In some embodiments, the transmission member may be fixedly connected to the flexible screen by screws or glue. The transmission member may be arranged at edges of the flexible screen located on both sides of the first direction, which may prevent the transmission member from blocking the display area and facilitate the connection with the driver.

In embodiments of the present disclosure, the transmission member may include a rack. In some embodiments, the rack may be fixedly connected to a sidewall of the flexible screen. The of the rack may face the first surface or the back of the first surface to facilitate the rack to be connected to the driver. The driver may include a gear and a motor. An output shaft of the motor is fixedly connected to the gear to drive the gear to rotate. The gear may mesh with the rack. During the rotation of the gear, the gear may drive the rack to move to drive the flexible screen to move in the first direction or the direction opposite to the first direction.

In other embodiments of the present disclosure, the transmission member may also include an electric push rod. In some embodiments, an end of the electric push rod may be fixedly connected to a sidewall of the flexible screen assembly. The other end of the electric push rod may be fixedly connected to the first body. The electric push rod may be extended to drive the flexible screen assembly to move along the first direction. The electric push rod may be retracted to drive the flexible screen assembly to move in the direction opposite to the first direction.

In other embodiments of the present disclosure, the transmission member may also include an elastic member, such as a spring. In some embodiments, an end of the elastic member may be fixedly connected to the flexible screen assembly. The other end of the elastic member may be fixedly connected to the first body. When the elastic member is being extended, the flexible screen assembly may move in the first direction. When the elastic member is being retracted, the flexible screen assembly may move in a direction opposite to the first direction. For maintaining the elastic member stably to be in a compressed state, a position limiting member may be used to limit a relative position between the flexible screen and the first body. When the flexible screen assembly needs to be in the storage state, the user may apply an external force to the flexible screen assembly to compress the elastic member. Then, the position limiting member may be configured to maintain the relative position between the flexible screen and the first body fixed. When the flexible screen needs to be in an extended state, the position limit may be canceled for the position limiting member. Thus, the flexible screen may move to the extended state along the first direction under the elastic force of the elastic member.

Only some embodiments of the present disclosure are described above and are not used to limit the present disclosure. For those skilled in the art, various modifications and changes may be made to the present disclosure. Any modification, equivalent replacement, and improvement made within the spirit and principle of the present disclosure shall be within the scope of the present disclosure.

What is claimed is:

1. An electronic apparatus comprising:
a first body including a first surface;
a second body rotatably connected to the first body and including a second surface neighboring to the first surface, the first surface and the second surface forming a folded state with an included angle not greater than a predetermined angle and an unfolded state with the included angle greater than the predetermined angle;
a flexible screen assembly including a first member and a second member, in the folded state, the first member being connected to the first body and covering the first surface, and the second member being slidably connected to the second body; and
a driver connected to the flexible screen assembly and configured to drive the flexible screen assembly to move in a first direction in the unfolded state;
wherein the first direction is a direction from the second body to the first body.

2. The electronic apparatus of claim 1, wherein in the unfolded state:
the first member in the flexible screen assembly increases gradually as the flexible screen assembly moves along the first direction.

3. The electronic apparatus of claim 1, wherein:
in the folded state, the second member covers the second surface; and
a functional area is arranged at a part of the first surface away from the second surface, and in the unfolded state, the functional area is gradually exposed as the flexible screen assembly moves along the first direction.

4. The electronic apparatus of claim 3, wherein the driver includes:
a first driver arranged at the first body and configured to drive the flexible screen assembly to move along the first direction; and
a second driver arranged at the second body and configured to drive the flexible assembly to move along a direction opposite to the first direction.

5. The electronic apparatus of claim 4, wherein:
the first driver is close to an end of the second surface away from the first surface; and/or the second drive is close to an end of the functional area close to the second surface.

6. The electronic apparatus of claim 3, wherein:
the first member is slidably connected to the first body;
the first surface and the second surface include guide grooves cooperating with each other; and
the flexible screen assembly is at least partially located in the guide grooves to be slidably connected to the first body and the second body.

7. The electronic apparatus of claim 1, wherein:
the second body includes an accommodation chamber; and
in the folded state, the second member is located in the accommodation chamber.

8. The electronic apparatus of claim 7, wherein the first body includes:
a fixed member rotatably connected to the second body;
a slide member slidably connected to the fixed member, a sliding direction of the slide member relative to the fixed member being along a direction of approaching to and being away from the fixed member, and the first member being fixedly connected to the slide member.

9. The electronic apparatus of claim 1, wherein the flexible screen assembly includes:
a flexible screen configured to cover the first surface; and
a transmission member fixedly connected to the flexible screen, the transmission member being transmission-connected to the driver such that the driver drives the flexible screen to move along the first direction.

10. The electronic apparatus of claim 9, wherein:
the transmission member is a rack; and
the driver includes a gear and a motor, an output shaft of the motor being fixedly connected to the gear, and the gear meshing with the rack.
